(19) United States
(12) Patent Application Publication
(10) Pub. No.: US 2021/0393029 A1
(43) Pub. Date: Dec. 23, 2021

(54) ROLLING MODULE STRUCTURE AND METHOD FOR USE THEREWITH

(71) Applicant: DTECH PRECISION INDUSTRIES CO., LTD., New Taipei City (TW)

(72) Inventor: TING-JUI WANG, New Taipei City (TW)

(21) Appl. No.: 17/338,715

(22) Filed: Jun. 4, 2021

(30) Foreign Application Priority Data
Jun. 22, 2020 (TW) 109121134

(51) Int. Cl. A47B 88/41; A47B 88/477; H05K 7/14

(52) U.S. Cl. CPC A47B 88/41; A47B 88/477; A47B 2210/0091; A47B 2210/0043; A47B 2210/0056; H05K 7/1489

(57) ABSTRACT

A rolling module structure and a method for use therewith are introduced. The rolling module structure includes a carrier and at least one rolling member. The rolling member is fitted to the carrier to form a rolling module structure. The rolling module structure is fitted to a moving target, allowing the moving target to move smoothly because of the rolling member.

### CROSS-REFERENCE TO RELATED APPLICATION

This non-provisional application claims priority under 35 U.S.C. § 119(a) on Patent Application No(s). 109121134 filed in Taiwan, R.O.C. on Jun. 22, 2020, the entire contents of which are hereby incorporated by reference.

### BACKGROUND OF THE INVENTION

### 1. Field of the Invention

The present disclosure relates to a rolling module structure and a method for use therewith, and in particular to a rolling module structure and a method for use therewith to allow the moving target to move smoothly.

### 2. Description of the Related Art

Conventionally, a moving target disposed in a cabinet or chest (for example, a box, casing or server) can move within the cabinet or chest by means of direct contact or rails. However, the moving target carries a heavy load and thus cannot move smoothly.

### BRIEF SUMMARY OF THE INVENTION

In at least one embodiment of the present disclosure, the present disclosure provides a rolling module structure and a method for use therewith to fit the rolling module structure and a moving target together, such that the moving target can move smoothly.

The present disclosure provides a rolling module structure, comprising a carrier and at least one rolling member fitted to the carrier to form the rolling module structure.

Optionally, the rolling module structure is fitted to a moving target, such that the moving target enters a movable state, wherein the moving target is in non-flattened state or non-leveled state, such that the rolling module structure is fitted to a fitting zone of the moving target and supported by the fitting zone, allowing the moving target to enter flattened state or leveled state.

Optionally, the rolling member is fitted to the carrier by a connecting element.

Optionally, the carrier is cord-shaped, L-shaped, H-shaped, block-shaped, n-shaped, square-shaped, rail-shaped, O-shaped, rod-shaped or is a structure comprising multiple rods.

Optionally, the moving target is disposed in a cabinet, chest or box.

Alternatively, the cabinet, the chest or the box has a support structure. The support structure supports the moving target having the rolling module structure.

Optionally, the rolling module structure is disposed in a cabinet, chest or box. Alternatively, the cabinet, the chest or the box has a support structure. The support structure holds the rolling module structure whereby the moving target rolls.

Optionally, a moving target having the rolling module structure is disposed in a cabinet, chest or box to allow the rolling member to roll on the support structure, such that the moving target having the rolling module structure rolls or rollingly separates from the cabinet, the chest or the box because of the rolling module structure.

Optionally, a moving target is disposed in a cabinet, chest or box having the rolling module structure, such that the moving target rolls or rollingly separates from the cabinet, the chest or the box because of the rolling module structure.

Optionally, the rolling module structure further comprises a repair platform or a repair system for supporting a moving target separated from a cabinet, chest or box.

Optionally, the repair platform or the repair system is a platform system or robot system that elevates, moves or carries a human being.

Optionally, the carrier is of greater thickness or hardness than the moving target to increase structural strength of the moving target, reinforce the moving target not deformed, or correct or reduce degree of deformation of the moving target.

Optionally, the rolling module structure is made of metal, stainless steel or carbon steel, which is hardened by heat treatment.

Optionally, the rolling member is fitted to the carrier by riveting, expanded connection, fastening, welding or engagement, or the rolling member and the carrier are integrally formed.

Optionally, the rolling member has a feeding space and has greater hardness than the carrier, such that the rolling member is riveted to the carrier, allowing material of the carrier to enter or flow into the feeding space, thereby allowing the rolling member to be fitted to the carrier.

Optionally, the rolling member and the carrier are fitted together by a connecting element, with the connecting element being a bolt member, engaging element, riveting member, expanded connection member, blind rivet or rivet.

Optionally, the connecting element corresponds in position to and fits to a connecting portion of the rolling member or the carrier.

Optionally, the rolling module structure has at least another rolling member for lowering the friction of the rolling member.

Optionally, the rolling module structure adjusts, corrects or flattens the moving target by 0.001 mm˜10 mm.

Optionally, the rolling module structure is mounted on a moving target to adjust structural stress-induced non-levelness or non-flatness of the moving target.

Optionally, the rolling module structure is mounted on an object to adjust structural stress-induced non-levelness or non-flatness of the object.

Optionally, the rolling module structure adjusts, corrects or flattens the object.

Optionally, the rolling module structure has a buffering portion or damping portion for buffering or damping a moving target in motion or not in motion.

Optionally, the buffering portion or the damping portion is a spring, resilient plate, resilient member, resilient cylinder, buffer pad, shock absorbing pad, buffer member or shock absorbing member.

Optionally, one end of the buffering portion or one end of the damping portion abuts against the rolling module structure, the rolling member or a structure connected to the rolling member, and the other end of the buffering portion or the other end of the damping portion abuts against the carrier or the moving target.

Optionally, the rolling member is a roller member, ball member or chain-shaped member.

Optionally, the rolling module structure is disposed in a cabinet, chest or box, a support structure of the cabinet, the chest or the box, a moving target, or a support structure of the moving target.

Optionally, the rolling module structure, moving target, chest, cabinet or support structure has an engaging element, and the engaging element allows the rolling module structure to engagingly stop at or be engagingly stopped at an object, support structure, cabinet, chest or box.

Optionally, the engaging element is a cylinder, thread member, outer engaging element, inner engaging element, resilient engaging element, hook engaging element, lever, or resilient engaging structure which has a sleeve or spring.

Optionally, a surface or inside of the rolling member has a lubricative material for lowering friction, and the lubricative material is a lubricative agent, lubricative oil, Teflon, liquid, solid-state member or glue member.

Optionally, the rolling module structure has a pulling portion for pulling or operating the rolling module structure or a moving target.

Optionally, the rolling module structure is mounted on a server, storage, power device, drawer, cabinet, chest, box, casing, motherboard or PCB.

Optionally, the rolling module structure is integrally formed with a drawer, cabinet, casing, plate, server, storage, power device, chest, box, motherboard or PCB, or the carrier of the rolling module structure is integrally formed with a drawer, cabinet, casing, plate, server, storage, power device, chest, box, motherboard or PCB.

Optionally, the carrier or the rolling member supports a drawer, cabinet, casing, plate, rod, server, cooler, storage, hard disk drive, battery, power device, chest, box, motherboard or PCB.

The present disclosure further provides a method for use with the rolling module structure. The rolling module structure is fitted to a moving target, such that the moving target enters a movable state, allowing the moving target to move within a cabinet, chest or box because of the rolling member.

The present disclosure further provides a method for use with the rolling module structure. The rolling module structure is fitted to a cabinet, chest, box or support structure, such that the moving target enters a movable state, allowing the moving target to move within a cabinet, chest or box because of the rolling member.

### BRIEF DESCRIPTION OF THE DRAWINGS

FIG. 1 is a perspective view of the 1st embodiment of the present disclosure.

FIG. 2 is a perspective view of the 2nd embodiment of the present disclosure.

FIG. 3 is a perspective view of the 3rd embodiment.

FIG. 4 is a perspective view of the 4th embodiment of the present disclosure.

FIG. 5 is a perspective view of the 5th embodiment of the present disclosure.

FIG. 6 is an exploded view of the 6th embodiment of the present disclosure.

FIG. 7 is a perspective view of the 6th embodiment of the present disclosure.

FIG. 8 is another perspective view of the 6th embodiment of the present disclosure.

FIG. 9 is a perspective view of the 7th embodiment of the present disclosure.

FIG. 10 is a perspective view of the 8th embodiment of the present disclosure.

FIG. 11 is a schematic view of the 9th embodiment of the present disclosure.

FIG. 12 is a schematic view of the 10th embodiment of the present disclosure.

FIG. 13 is a schematic view of the 11th embodiment of the present disclosure.

FIG. 14 is a schematic view of the 12th embodiment of the present disclosure.

FIG. 15 is a schematic view of the 13th embodiment of the present disclosure.

FIG. 16 is a schematic view of the 14th embodiment of the present disclosure.

FIG. 17 is a schematic view of the 15th embodiment of the present disclosure.

FIG. 18 is a schematic view of the 16th embodiment of the present disclosure.

FIG. 19A is a schematic view of the 17th embodiment of the present disclosure.

FIG. 19B is another schematic view of the 17th embodiment of the present disclosure.

FIG. 20 is a schematic view of the 18th embodiment of the present disclosure.

FIG. 21 is a schematic view of the 19th embodiment of the present disclosure.

FIG. 22 is a schematic view of the 20th embodiment of the present disclosure.

FIG. 23 is a schematic view of the 21st embodiment of the present disclosure.

FIG. 24 is a schematic view of the 22nd embodiment of the present disclosure.

FIG. 25 is a schematic view of the 23rd embodiment of the present disclosure.

FIG. 26 is a schematic view of the 24th embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

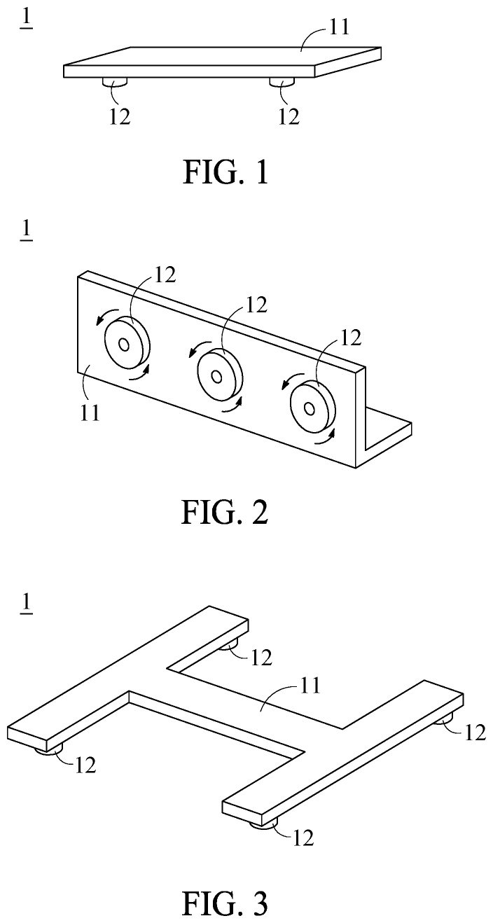

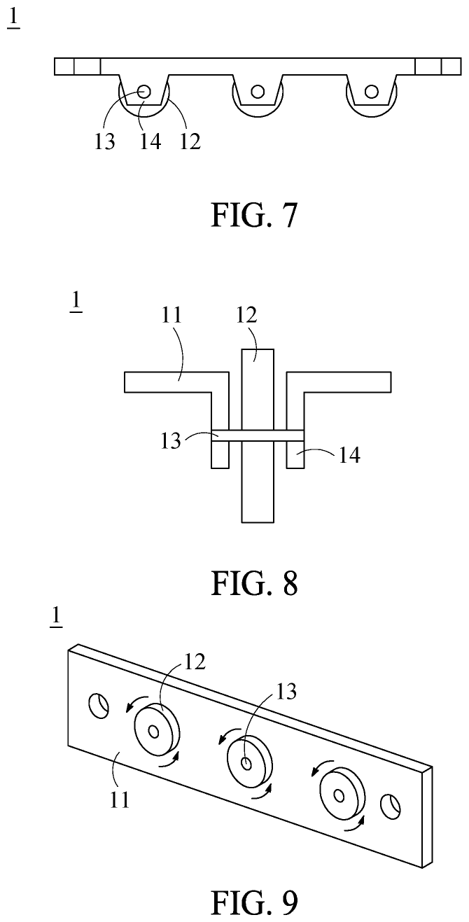

Referring to FIG. 1 through FIG. 9, the present disclosure provides a rolling module structure and a method for use therewith. The rolling module structure 1 comprises a carrier 11 and at least one rolling member 12. The rolling member 12 is fitted to the carrier 11 to form the rolling module structure 1.

To use the rolling module structure 1, a user fits the rolling module structure 1 to a moving target 10 (as shown in FIG. 5). The moving target 10 is a box, casing or server, such that the moving target 10 enters a movable state, allowing the moving target 10 to move smoothly because of the rolling member 12.

In a variant embodiment, the rolling module structure 1 is mounted on a server, storage, power device, drawer, cabinet, chest, casing, motherboard or PCB, so as to meet practical operation needs.

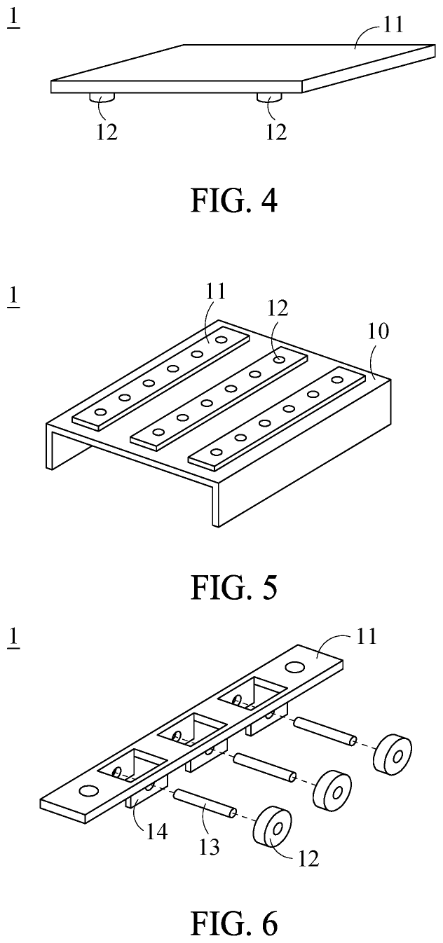

In an embodiment of the present disclosure, the carrier 11 is cord-shaped (as shown in FIG. 1), L-shaped (as shown in FIG. 2), H-shaped (as shown in FIG. 3), block-shaped (as shown in FIG. 4), n-shaped, square-shaped, rail-shaped, O-shaped, rod-shaped or structure comprising multiple rods. Thus, the carrier 11 in any aforesaid shape can be in use to meet practical usage needs.

In an embodiment of the present disclosure, the rolling member 12 is fitted to the carrier 11 by a connecting element 13 (as shown in FIG. 6 through FIG. 8). The connecting element 13 is fitted to a connecting portion 14 of the carrier 11 (or the rolling member 12). The connecting element 13 is a bolt member, engaging element, riveting member, expanded connection member, blind rivet or rivet. In a variant embodiment, the rolling member 12 is fitted to the carrier 11 by the connecting element 13 (as shown in FIG. 9). Thus, the rolling member 12 is fitted firmly to the carrier 11 by the connecting element 13 to stabilize the rolling course of the rolling member 12.

In an embodiment of the present disclosure, the rolling module structure 1 is made of metal, stainless steel or carbon steel, which is hardened by heat treatment. Thus, structural strength of the rolling module structure 1 is augmented to thereby facilitate the smooth movement of the moving target.

In an embodiment of the present disclosure, the rolling member 12 is a roller member, ball member or chain-shaped member. Thus, the rolling member 12 can be in any aforesaid shape to meet practical usage needs.

In an embodiment of the present disclosure, the rolling module structure 1 is integrally formed with a drawer, cabinet, casing, plate, server, storage, power device, chest, box, motherboard or PCB. In a variant embodiment, the carrier 11 of the rolling module structure 1 is integrally formed with a drawer, cabinet, casing, plate, server, storage, power device, chest, box, motherboard or PCB.

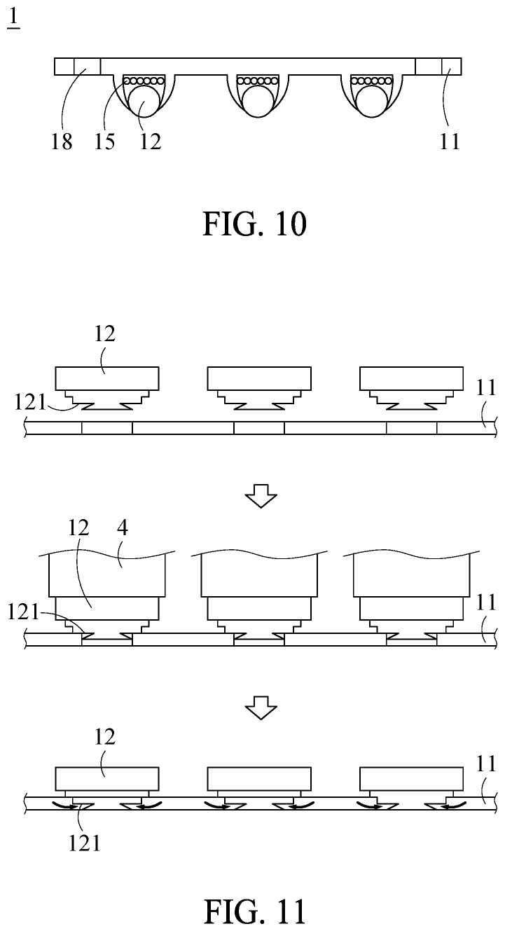

Referring to FIG. 10, the rolling module structure 1 has at least another rolling member 15 for lowering the friction of the rolling member 12. Thus, the rolling member 12 can move smoothly because of the another rolling member 15. The carrier 11 of the rolling module structure 1 has a fitting portion 18. The fitting portion 18 and a fastening element together allow the rolling module structure 1 to be fitted to the moving target 10.

Referring to FIG. 11, in an embodiment of the present disclosure, the rolling member 12 has a feeding space 121 and has greater hardness than the carrier 11, such that the rolling member 12 is riveted to the carrier 11 when compressed by a tool 40, allowing the material of the carrier 11 to enter or flow into the feeding space 121, thereby allowing the rolling member 12 to be fitted to the carrier 11. Thus, the rolling member 12 and the carrier 11 are firmly fitted together.

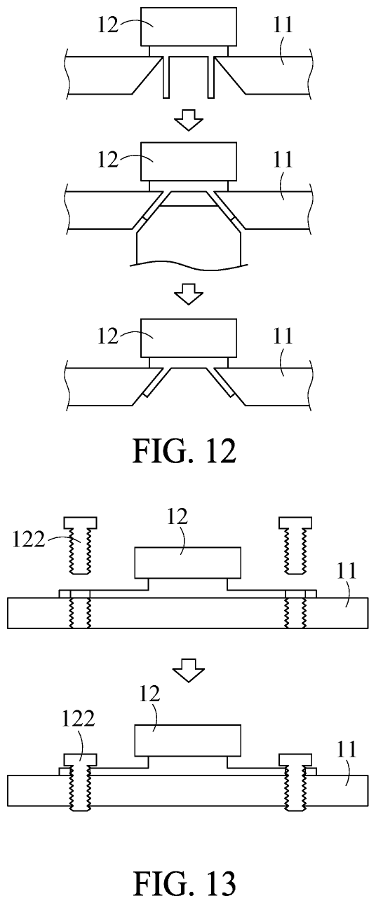

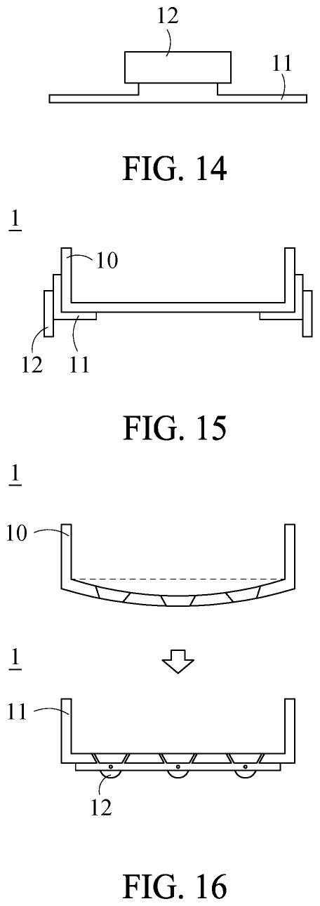

Referring to FIG. 12 through FIG. 14, in an embodiment of the present disclosure, the rolling member 12 is fitted to the carrier 11 by riveting, expanded connection (as shown in FIG. 12), fastening with a fastening element 122 (as shown in FIG. 13), welding or engagement, or the rolling member 12 is integrally formed with the carrier 11 (as shown in FIG. 14). Thus, the rolling member 12 and the carrier 11 are firmly fitted together.

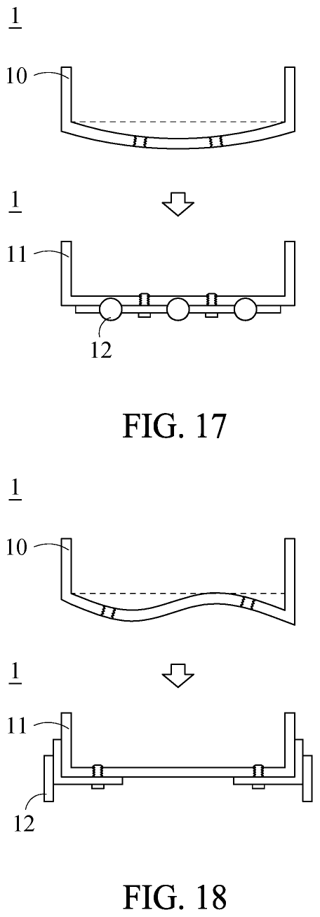

Referring to FIG. 15 through FIG. 18, in an embodiment of the present disclosure, to start using the rolling module structure 1, a user fits the rolling module structure 1 to the moving target 10 (such as a box, casing or server), such that the moving target 10 enters a movable state, allowing the moving target 10 to move smoothly because of the rolling member 12.

The rolling module structure 1 is mounted on the moving target 10 (or the object) to adjust the structural stress-induced non-levelness or non-flatness of the moving target 10 (or the object).

The moving target 10 is in non-flattened state or non-leveled state. The rolling module structure 1 is fitted to a fitting zone of the moving target 10 and supported by the fitting zone, such that the moving target 10 is in flattened state or in leveled state. The rolling module structure 1 (or a structure fitted to the rolling member 12) adjusts, corrects or flattens the moving target 10 (or the object) by 0.001 mm˜10 mm. Thus, owing to the rolling module structure 1, the moving target 10 is flatly supported, and thus the moving target 10 can move smoothly because of the rolling member 12.

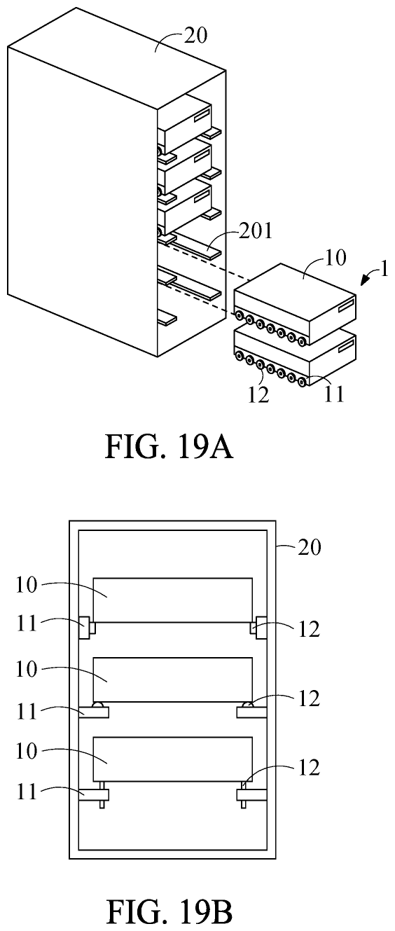

Referring to FIG. 19A and FIG. 19B, in an embodiment of the present disclosure, the moving target 10 is disposed in the cabinet 20 (or chest and box). The cabinet 20 (or the chest and the box) has a support structure 201. The support structure 201 supports the moving target 10 having the rolling module structure 1.

The moving target 10 having the rolling module structure 1 is mounted on the support structure 20 of the cabinet 10 (or the chest and the box), such that the rolling member 12 rolls on the support structure 20. As a result, the moving target 10 having the rolling module structure 1 rolls or rollingly separates from the cabinet 10 (or the chest and the box) because of the rod-shaped rolling member 12. Alternatively, the moving target 10 rolls and enters the cabinet 10 because of the rod-shaped rolling member 12. Thus, the moving target 10 can move smoothly because of the rolling member 12.

In an embodiment of the present disclosure, the carrier 11 is of greater thickness or hardness than the moving target 10 to increase structural strength of the moving target 10, reinforce the moving target 10 not deformed, or correct or reduce degree of deformation of the moving target 10. Thus, the moving target 10 can be loaded with a loading mechanism component, motherboard or electronic part/component and moved because of the rolling of the rolling member 12. Therefore, the moving target 10 moves smoothly because of the rolling member 12.

In an embodiment of the present disclosure, the cabinet 20 (or the chest and the box), the moving target 10, or a support structure (not shown) of the moving target 10 is adapted to support the rolling module structure 1 or fit to the rolling member 12. Thus, the present disclosure meets practical operation needs.

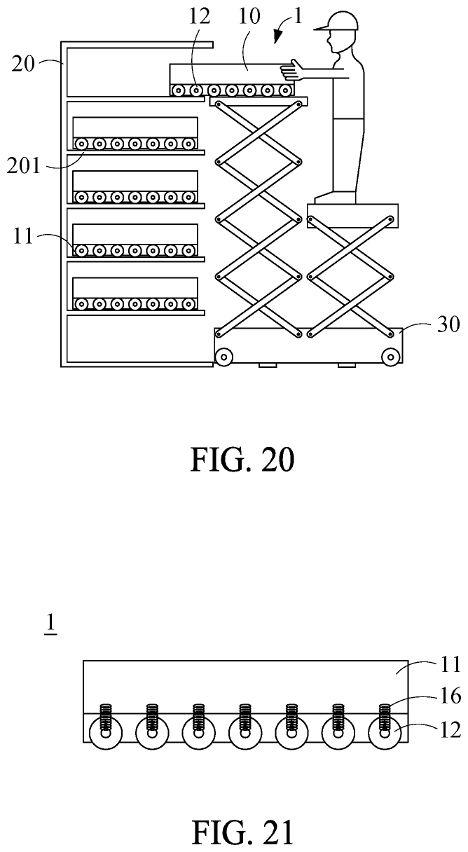

Referring to FIG. 20, in an embodiment of the present disclosure, the rolling module structure 1 further comprises a repair platform 30 (or a repair system). The repair platform 30 supports the moving target 10 separated from the cabinet 20 (or the chest and the box). The repair platform 30 (or the repair system) is a platform system or robot system that elevates, moves or carries a human being (such as a repair technician) to a required height, moving the moving target 10 into or out of the cabinet 20 because of the rolling member 12, thereby meeting practical operation needs.

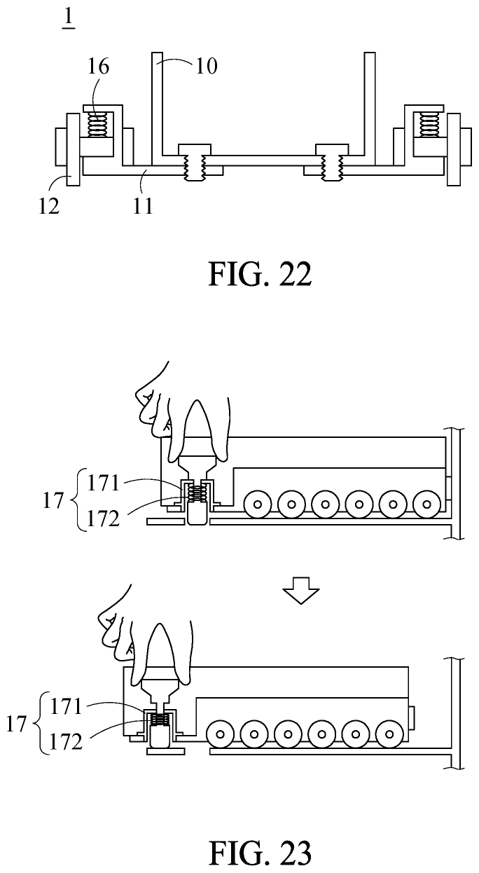

Referring to FIG. 21 and FIG. 22, in an embodiment of the present disclosure, the rolling module structure 1 (or a structure fitted to the rolling member 12) has a buffering portion 16 (or a damping portion) for buffering (or damping) the moving target 10 in motion or not in motion.

In an embodiment of the present disclosure, the buffering portion 16 (or the damping portion) is a spring, resilient plate, resilient member, resilient cylinder, buffer pad, shock absorbing pad, buffer member or shock absorbing member and thereby can meet different buffering or damping needs.

In an embodiment of the present disclosure, one end of the buffering portion 16 (or the damping portion) abuts against the rolling module structure 1 (or a structure fitted to the rolling member 12), whereas the other end of the buffering portion 16 (or the damping portion) abuts against the rolling member 12 (as shown in FIG. 20). Alternatively, the other end of the buffering portion 16 (or the damping portion) abuts against the connecting portion 14 (as shown in FIG. 20). Thus, the buffering portion 16 meets the needs for different buffering positions or damping positions.

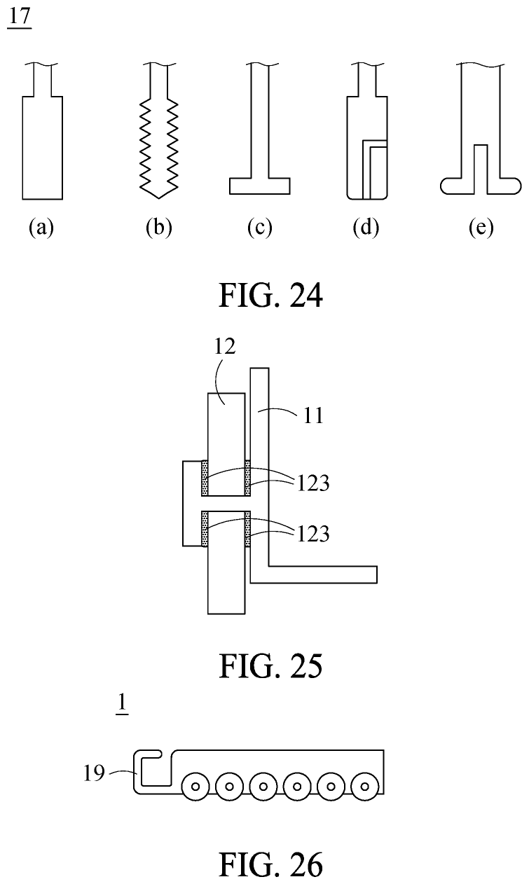

Referring to FIG. 23 and FIG. 24, in an embodiment of the present disclosure, the rolling module structure 1 has an engaging element 17 (or the moving target 10, the chest, the cabinet 20, the box or the support structure 201 has an engaging element 17, not shown). The engaging element 17 allows the rolling module structure 1 to engagingly stop at (or be engagingly stopped at) an object, support structure 201, cabinet 20, chest or box. Thus, after the moving target 10 has moved into or out of the cabinet 20, the engaging element 17 limits the movement of the moving target 10, allowing the moving target 10 to be fixed in place.

In an embodiment of the present disclosure, the engaging element 17 is a cylinder (part a in FIG. 24), thread member (part b in FIG. 24), outer engaging element (part c in FIG. 24), inner engaging element (part d in FIG. 24), resilient engaging element (part e in FIG. 24), hook engaging element, lever, or resilient engaging structure which has a sleeve 171 and spring 172. Thus, the engaging element 17 can meet different engagement needs.

Referring to FIG. 25, in an embodiment of the present disclosure, the surface or inside of the rolling member 12 has a lubricative material 123 for lowering friction. The lubricative material is a lubricative agent, lubricative oil, Teflon, liquid, solid-state member or glue member. Thus, the rolling member 12 and the lubricative material 123 together allow the moving target 10 to move smoothly.

Referring to FIG. 26, the rolling module structure 1 has a pulling portion 19 for pulling or operating the rolling module structure 1 (or operating the moving target 10), thereby meeting various operation needs.

In conclusion, a rolling module structure and a method for use therewith, as provided in embodiments of the present disclosure, are characterized in that the rolling module structure is fitted to a moving target, such that the moving target can move smoothly because of a rolling member.

While the present disclosure has been described by means of specific embodiments, numerous modifications and variations could be made thereto by those skilled in the art without departing from the scope and spirit of the present disclosure set forth in the claims.

What is claimed is:

1. A rolling module structure, comprising a carrier and at least one rolling member fitted to the carrier to form a rolling module structure.

2. The rolling module structure of claim 1, wherein the rolling module structure is fitted to a moving target, such that the moving target enters a movable state, wherein the moving target is in non-flattened state or non-leveled state, such that the rolling module structure is fitted to a fitting zone of the moving target and supported by the fitting zone, allowing the moving target to enter flattened state or leveled state.

3. The rolling module structure of claim 1, wherein the rolling member is fitted to the carrier by a connecting element.

4. The rolling module structure of claim 2, wherein the moving target is disposed in a cabinet, chest or box, or the cabinet, the chest or the box has a support structure for supporting the moving target having the rolling module structure.

5. The rolling module structure of claim 1, wherein the rolling module structure is disposed in a cabinet, chest or box, or the cabinet, the chest or the box houses the rolling module structure whereby a moving target rolls.

6. The rolling module structure of claim 1, wherein a moving target having the rolling module structure is disposed in a cabinet, chest or box to allow the rolling member to roll on the support structure, such that the moving target having the rolling module structure rolls or rollingly separates from the cabinet, the chest or the box because of the rolling module structure.

7. The rolling module structure of claim 1, wherein a moving target is disposed in a cabinet, chest or box having the rolling module structure, such that the moving target rolls or rollingly separates from the cabinet, the chest or the box because of the rolling module structure.

8. The rolling module structure of claim 1, further comprising a repair platform or a repair system for supporting a moving target separated from a cabinet, chest or box.

9. The rolling module structure of claim 1, wherein the carrier is of greater thickness or hardness than the moving target to increase structural strength of the moving target, reinforce the moving target not deformed, or correct or reduce degree of deformation of the moving target.

10. The rolling module structure of claim 1, wherein the rolling member has a feeding space and has greater hardness than the carrier, such that the rolling member is riveted to the carrier, allowing material of the carrier to enter or flow into the feeding space, thereby allowing the rolling member to be fitted to the carrier.

11. The rolling module structure of claim 1, wherein the rolling member is fitted to the carrier by a connecting element, and the connecting element is a bolt member, engaging element, riveting member, expanded connection member, blind rivet or rivet.

12. The rolling module structure of claim 1, wherein the connecting element corresponds in position to and fits to a connecting portion of the rolling member or the carrier

13. The rolling module structure of claim 1, wherein the rolling module structure has at least another rolling member for lowering friction of the rolling member.

14. The rolling module structure of claim 1, wherein the rolling module structure adjusts, corrects or flattens a moving target by 0.001 mm-10 mm.

15. The rolling module structure of claim 1, wherein the rolling module structure is mounted on a moving target to adjust structural stress-induced non-levelness or non-flatness of the moving target.

16. The rolling module structure of claim 1, wherein the rolling module structure is mounted on an object to adjust structural stress-induced non-levelness or non-flatness of the object.

17. The rolling module structure of claim 1, wherein the rolling module structure adjusts, corrects or flattens an object.

18. The rolling module structure of claim 1, wherein the rolling module structure has a buffering portion or damping portion for buffering or damping a moving target in motion or not in motion.

19. The rolling module structure of claim 1, wherein an end of the buffering portion or an end of the damping portion abuts against the rolling module structure, the rolling member or a structure connected to the rolling member, and another end of the buffering portion or another end the damping portion abuts against the carrier or the moving target.

20. The rolling module structure of claim 1, wherein the rolling module structure, moving target, chest, cabinet, box or support structure has an engaging element, and the engaging element allows the rolling module structure to engagingly stop at or be engagingly stopped at an object, support structure, cabinet, chest or box.

21. The rolling module structure of claim 1, wherein a surface or inside of the rolling member has a lubricative material for lowering friction, and the lubricative material is a lubricative agent, lubricative oil, Teflon, liquid, solid-state member or glue member.

22. The rolling module structure of claim 1, wherein the rolling module structure has a pulling portion for pulling or operating the rolling module structure or a moving target.

23. The rolling module structure of claim 1, wherein the rolling module structure is integrally formed with a drawer, cabinet, casing, plate, server, storage, power device, chest, box, motherboard or PCB, or the carrier of the rolling module structure is integrally formed with a drawer, cabinet, casing, plate, server, storage, power device, chest, box, motherboard or PCB.

24. The rolling module structure of claim 1, wherein the carrier or the rolling member supports a drawer, cabinet, casing, plate, rod, server, cooler, storage, hard disk drive, battery, power device, chest, box, motherboard or PCB.

25. A method for use with the rolling module structure of claim 1, wherein the rolling module structure is fitted to a moving target, such that the moving target enters a movable state, allowing the moving target to move within a cabinet, chest or box because of the rolling member.

26. A method for use with the rolling module structure of claim 1, wherein the rolling module structure is fitted to a cabinet, chest, box or support structure, such that the moving target enters a movable state, allowing the moving target to move within a cabinet, chest or box because of the rolling member.
